(19) United States
(12) Patent Application Publication
(10) Pub. No.: US 2018/0194978 A1
(43) Pub. Date: Jul. 12, 2018

(54) ADHESIVE COMPOSITION, IN PARTICULAR FOR ENCAPSULATING AN ELECTRONIC ARRANGEMENT

(71) Applicant: TESA SE, Norderstedt (DE)

(72) Inventors: Thilo DOLLASE, Hamburg (DE); Thorsten KRAWINKEL, Hamburg (DE); Klaus KEITE-TELGENBÜSCHER, Hamburg (DE); Christian SCHUH, Hamburg (DE); Jessika GARGIULO, Hamburg (DE)

(21) Appl. No.: 15/736,219

(22) PCT Filed: May 27, 2016
(86) PCT No.: PCT/EP2016/062033

§ 371 Date: Dec. 13, 2017

(30) Foreign Application Priority Data
Jun. 29, 2015 (DE) 102015212058.9

(51) Int. Cl. C09J 153/00; C03C 27/10; C09J 163/00; C08J 3/00; C08L 21/00; C08L 53/00; C08L 63/00; H01L 31/048; H01L 33/00

(52) U.S. Cl. CPC C09J 153/00; C03C 27/10; C09J 163/00; C08J 3/00; C08L 21/00; H01L 51/5246; C08L 63/00; H01L 31/0481; H01L 33/00; H01L 2924/0002; C08L 53/00

(57) ABSTRACT

The invention relates to an adhesive composition, preferably pressure-sensitive adhesive composition, comprising a) at least one (co)polymer containing at least isobutylene and/or butylene as comonomer type and, optionally but preferably, at least one comonomer type that—when considered in hypothetical homopolymer form—has a softening point above 40° C., b) at least one type of at least partially hydrogenated adhesive resin, c) at least one type of reactive resin based on a cyclic ether with a softening point below 40° C., preferably below 20° C., d) at least one type of latently reactive thermally activatable initiator for initiating cationic curing.

The present invention relates to an adhesive particularly for encapsulating an electronic arrangement.

(Opto)electronic arrangements are being used with ever-increasing frequency in commercial products or are close to market introduction. Such arrangements comprise organic or inorganic electronic structures, examples being organic, organometallic or polymeric semiconductors or else combinations of these. Depending on the desired application, these arrangements and products are rigid or flexible in form, there being an increasing demand for flexible arrangements. Arrangements of this kind are produced, for example, by printing techniques, such as relief, gravure, screen or planographic printing, or else what is called “non-impact printing”, such as, for instance, thermal transfer printing, inkjet printing or digital printing. In many cases, however, vacuum techniques are used as well, such as chemical vapour deposition (CVD), physical vapour deposition (PVD), plasma-enhanced chemical or physical deposition techniques (PECVD), sputtering, (plasma) etching or vapour coating, with patterning taking place generally through masks.

Examples of (opto)electronic applications that are already commercial or are of interest in terms of their market potential include electrophoretic or electrochromic constructions or displays, organic or polymeric light-emitting diodes (OLEDs or PLEDs) in readout and display devices, or as illumination, electroluminescent lamps, light-emitting electrochemical cells (LEECs), organic solar cells, preferably dye or polymer solar cells, inorganic solar cells, preferably thin-film solar cells, more particularly those based on silicon, germanium, copper, indium and/or selenium, organic field-effect transistors, organic switching elements, organic optical amplifiers, organic laser diodes, organic or inorganic sensors or else organic- or inorganic-based RFID transponders.

A perceived technical challenge for realization of sufficient lifetime and function of (opto)electronic arrangements in the area of organic and/or inorganic (opto)electronics, especially in the area of organic (opto)electronics, is the protection of the components they contain against permeants. Permeants may be a large number of low molecular mass organic or inorganic compounds, more particularly water vapour and oxygen.

A large number of (opto)electronic arrangements in the area of organic and/or inorganic (opto)electronics, especially where organic raw materials are used, are sensitive not only to water vapour but also to oxygen, and for many arrangements the penetration of water vapour is classed as a relatively severe problem. During the lifetime of the electronic arrangement, therefore, it requires protection by means of encapsulation, since otherwise the performance drops off over the period of application. For example, oxidation of the components, in the case of light-emitting arrangements such as electroluminescent lamps (EL lamps) or organic light-emitting diodes (OLEDs) for instance, may drastically reduce the luminosity, the contrast in the case of electrophoretic displays (EP displays), or the efficiency in the case of solar cells, within a very short time.

In organic and/or inorganic (opto)electronics, particularly in the case of organic (opto)electronics, there is a particular need for flexible bonding solutions which constitute a permeation barrier to permeants, such as oxygen and/or water vapour. In addition there are a host of further requirements for such (opto)electronic arrangements. The flexible bonding solutions are therefore intended not only to achieve effective adhesion between two substrates, but also, in addition, to fulfill properties such as high shear strength and peel strength, chemical stability, aging resistance, high transparency, ease of processing, and also high flexibility and pliability.

One approach common in the prior art, therefore, is to place the electronic arrangement between two substrates that are impermeable to water vapour and oxygen. This is then followed by sealing at the edges. For non-flexible constructions, glass or metal substrates are used, which offer a high permeation barrier but are very susceptible to mechanical loads. Furthermore, these substrates give rise to a relatively high thickness of the arrangement as a whole. In the case of metal substrates, moreover, there is no transparency. For flexible arrangements, in contrast, sheetlike substrates are used, such as transparent or non-transparent films, which may have a multi-ply configuration. In this case it is possible to use not only combinations of different polymers, but also organic or inorganic layers. The use of such sheetlike substrates allows a flexible, extremely thin construction. For the different applications there are a very wide variety of possible substrates, such as films, wovens, nonwovens and papers or combinations thereof, for example.

In order to obtain the most effective sealing, specific barrier adhesives are used. A good adhesive for the sealing of (opto)electronic components has a low permeability for oxygen and particularly for water vapour, has sufficient adhesion to the arrangement, and is able to flow well onto the arrangement. Owing to incomplete wetting of the surface of the arrangement and owing to pores that remain, low capacity for flow on the arrangement may reduce the barrier effect at the interface, since it permits lateral ingress of oxygen and water vapour independently of the properties of the adhesive. Only if the contact between adhesive and substrate is continuous are the properties of the adhesive the determining factor for the barrier effect of the adhesive.

For the purpose of characterizing the barrier effect it is usual to state the oxygen transmission rate OTR and the water vapour transmission rate WVTR. Each of these rates indicates the flow of oxygen or water vapour, respectively, through a film per unit area and unit time, under specific conditions of temperature and partial pressure and also, optionally, further measurement conditions such as relative atmospheric humidity. The lower the values the more suitable the respective material for encapsulation. The statement of the permeation is not based solely on the values of WVTR or OTR, but instead also always includes an indication of the average path length of the permeation, such as the thickness of the material, for example, or a standardization to a particular path length.

The permeability P is a measure of the perviousness of a body for gases and/or liquids. A low P values denotes a good barrier effect. The permeability P is a specific value for a defined material and a defined permeate under steady-state conditions and with defined permeation path length, partial pressure and temperature. The permeability P is the product of diffusion term D and solubility term S: P=D*S

The solubility term S describes in the present case the affinity of the barrier adhesive for the permeate. In the case of water vapour, for example, a low value for S is achieved by hydrophobic materials. The diffusion term D is a measure of the mobility of the permeate in the barrier material, and is directly dependent on properties, such as the molecular mobility or the free volume. Often, in the case of highly crosslinked or highly crystalline materials, relatively low values are obtained for D. Highly crystalline materials, however, are generally less transparent, and greater crosslinking results in a lower flexibility. The permeability P typically rises with an increase in the molecular mobility, as for instance when the temperature is raised or the glass transition point is exceeded.

A low solubility term S is usually insufficient for achieving good barrier properties. One classic example of this, in particular, are siloxane elastomers. The materials are extraordinarily hydrophobic (low solubility term), but as a result of their freely rotatable Si—O bond (large diffusion term) have a comparatively low barrier effect for water vapour and oxygen. For a good barrier effect, then, a good balance between solubility term S and diffusion term D is necessary.

Approaches at increasing the barrier effect of an adhesive must take account of the two parameters D and S, with a view in particular to their influence on the permeability of water vapour and oxygen. In addition to these chemical properties, thought must also be given to consequences of physical effects on the permeability, particularly the average permeation path length and interface properties (flow-on behaviour of the adhesive, adhesion). The ideal barrier adhesive has low D values and S values in conjunction with very good adhesion to the substrate.

For this purpose use has hitherto been made in particular of liquid adhesives and adhesives based on epoxides (WO 98/21287 A1; U.S. Pat. No. 4,051,195 A; U.S. Pat. No. 4,552,604 A). As a result of a high degree of crosslinking, these adhesives have a low diffusion term D. Their principal field of use is in the edge bonding of rigid arrangements, but also moderately flexible arrangements. Curing takes place thermally or by means of UV radiation. Full-area bonding is hard to achieve, owing to the contraction that occurs as a result of curing, since in the course of curing there are stresses between adhesive and substrate that may in turn lead to delamination.

Using these liquid adhesives harbours a series of disadvantages. For instance, low molecular mass constituents (VOCs—volatile organic compounds) may damage the sensitive electronic structures in the arrangement and may hinder production operations. The adhesive must be applied, laboriously, to each individual constituent of the arrangement. The acquisition of expensive dispensers and fixing devices is necessary in order to ensure precise positioning. Moreover, the nature of application prevents a rapid continuous operation, and the laminating step that is subsequently needed may also make it more difficult, owing to the low viscosity, to achieve a defined layer thickness and bond width within narrow limits.

Furthermore, the residual flexibility of such highly crosslinked adhesives after curing is low. In the low temperature range or in the case of 2-component systems, the use of thermally crosslinking systems is limited by the potlife, in other words the processing life until gelling has taken place. In the high temperature range, and particularly in the case of long reaction times, in turn, the sensitive (opto)electronic structures limit the possibility of using such systems—the maximum temperatures that can be employed in the case of (opto)electronic structures are often below 120° C., since at excessively high temperatures there may be initial damage. Flexible arrangements which comprise organic electronics and are encapsulated using transparent polymer films or assemblies of polymer films and inorganic layers, in particular, have narrow limits here. The same applies to laminating steps under high pressure. In order to achieve improved durability, it is advantageous here to forgo a temperature loading step and to carry out lamination under a relatively low pressure.

As an alternative to the thermally curable liquid adhesives, radiation-curing adhesives as well are now used in many cases (US 2004/0225025 A1, US 2010/0137530 A1, WO 2013/057265, WO 2008/144080 A1). The use of radiation-curing adhesives prevents long-lasting thermal load on the (opto)electronic arrangement.

Particularly if the (opto)electronic arrangements are to be flexible, it is important that the adhesive used is not too rigid and brittle even after curing. Accordingly, for this reason pressure-sensitive adhesives (PSAs) and heat-activatedly bondable adhesive sheets (unlike liquid adhesives) are particularly suitable in principle for such bonding. In order to flow well onto the substrate but at the same time to attain a high bonding strength, the adhesives ought initially to be very soft, but then to be able to be crosslinked. As crosslinking mechanisms it is possible, depending on the chemical basis of the adhesive, to implement thermal cures and/or radiation cures. While thermal curing is very slow, radiation cures can be initiated within a few seconds. Accordingly, radiation cures, more particularly UV curing, are often preferred, especially in the case of continuous production processes. Some sensitive (opto)electronics, however, are sensitive to the UV radiation that is necessary for the curing of such systems.

Suitable thermal curing methods which utilize a sufficiently low temperature range for activation, but at room temperature exhibit virtually no reactivity or none at all, with a reactive system compatible with the sensitive (opto)electronic arrangement, in other words not perceptibly damaging it and operating with economically acceptable cycle times in the context of curing, therefore continue to be sought.

DE 10 2008 060 113 A1 describes a method for encapsulating an electronic arrangement with respect to permeants, using a PSA based on butylene block copolymers, more particularly isobutylene block copolymers, and describes the use of such an adhesive in an encapsulation method. In combination with the elastomers, defined resins, characterized by DACP and MMAP values, are preferred. The adhesive, moreover, is preferably transparent and may exhibit UV-blocking properties. As barrier properties, the adhesive preferably has a WVTR of <40 g/m²*d and an OTR of <5000 g/m²*d bar. In the method, the PSA may be heated during and/or after application. The PSA may be crosslinked by radiation or thermally, for example. Classes of substance are proposed via which such crosslinking can be advantageously performed. However, no specific examples are given that lead to particularly low volume permeation and interfacial permeation in conjunction with high transparency and flexibility.

US 2006/100299 A1 discloses a PSA which comprises a polymer having a softening temperature, as defined in US 2006/100299 A1, of greater than +60° C., a polymerizable resin having a softening temperature, as defined in US 2006/100299 A1 of less than +30° C., and a latent-reactive, in particular photoactivatable initiator which is able to lead to a reaction between resin and polymer. Reactively equipped polymers, however, are not available universally, and so there are restrictions on the selection of this polymer basis when other properties and costs are an issue. Moreover, any kind of functionalization (for the purpose of providing reactivity) is accompanied by an increase in basic polarity and hence by an unwanted rise in water vapour permeability. No copolymers based on isobutylene or butylene are identified, and no information is given on molar masses of the polymers. The text discusses various drawbacks of the thermal curing for the encapsulation of OLEDs.

Thermally activatable adhesive systems for encapsulation, for example, of OLEDs are known (U.S. Pat. No. 5242715, WO 2015/027393 A1, WO 2015/068454 A1, JP 2015/050143 A1, KR 2009110132 A1, WO 2015/199626 A1). Here, however, the adhesive systems described are always liquid systems, with the corresponding drawbacks as stated earlier on above.

US 2014/0367670 A1 teaches thermally initiated, cationically curable formulations which can likewise be utilized for the encapsulation of OLEDs. For the curing of epoxy resins, quaternary ammonium compounds are stated. Curing temperatures indicated are a range between 70° C. and 150° C., more specifically between 80° C. and 110° C., and more specifically still between 90° C. and 100° C. The formulations can also be applied in film form. The reactive system may be admixed with polymers. For that purpose, by way of example, polymers with very different polarities are specified. Not specified, however, are polymers with a particularly good barrier effect, such as polyisobutylene or polybutylene. Instead, barrier properties are generated by introduction of an additional, passivation layer. The combination of a thermally activatable epoxide system with low activation temperature and a polyisobutylene- or polybutylene-containing matrix does not apparently seem to be obvious, or is estimated to be difficult to accomplish.

It is an object of the invention to provide a not readily yellowing adhesive which is able to prevent the harmful influence of oxygen and water vapour on sensitive functional layers such as, for example, in the area of organic photoelectric cells for solar modules, or in the area of organic light-emitting diodes (OLEDs), by means of a good barrier effect with respect to the harmful substances; which is able to join different components of the functional elements to one another; which is readily manageable in adhesive bonding operations; which allows a flexible and tidy processing; and which is nevertheless easy and economical to use for the producer.

This object is achieved by means of an adhesive as characterized in more detail in the main claim. The dependent claims describe advantageous embodiments of the invention. Also encompassed is the use of the adhesive of the invention and a composite which has been produced by bonding with the adhesive system of the invention.

The invention accordingly provides an adhesive, preferably a pressure-sensitive adhesive, comprising

(a) at least one (co)polymer comprising at least isobutylene and/or butylene as comonomer kind and, optionally but preferably, at least one comonomer kind which—considered as hypothetical homopolymer—has a softening temperature of greater than 40° C.,

(b) at least one kind of an at least partly hydrogenated tackifier resin,

(c) at least one kind of a reactive resin based on a cyclic ether having a softening temperature of less than 40° C., preferably of less than 20° C.,

(d) at least one kind of a latent-reactive thermally activatable initiator for initiating cationic curing.

In the case of amorphous substances, the softening temperature here corresponds to the glass transition temperature (test A) in the case of (semi-)crystalline substances, the softening temperature here corresponds to the melting temperature.

In the adhesives sector, pressure-sensitive adhesives (PSAs) are notable in particular for their permanent tack and flexibility. A material which exhibits permanent pressure-sensitive tack must at any given point in time feature a suitable combination of adhesive and cohesive properties. For good adhesion properties it is necessary to formulate PSAs for an optimum balance between adhesive and cohesive properties.

The adhesive is preferably a PSA, in other words a viscoelastic mass which remains permanently tacky and adhesive in the dry state at room temperature. Bonding is accomplished by gentle applied pressure, immediately, to virtually every substrate.

According to one preferred embodiment of the invention, the (co)polymer or (co)polymers is or are homopolymers or random, alternating, block, star and/or graft copolymers having a molar mass M_{w} (weight average) of 1 000 000 g/mol or less, preferably 500 000 g/mol or less. Smaller molar weights are preferred here on account of their better processing qualities. Higher molar weights, especially in the case of homopolymers, lead to increased cohesion of the formulation in the adhesive film. The molecular weight is determined via GPC (Test B).

Employed as homopolymer are polyisobutylene and/or polybutylene or mixtures of different polyisobutylenes and/or polybutylenes, in respect of their molecular weight, for example.

Copolymers used are, for example, random copolymers of at least two different monomer kinds, of which at least one is isobutylene or butylene. In addition to isobutylene and/or butylene, at least one further monomer kind very preferably used is a comonomer having—viewed as hypothetical homopolymer—a softening temperature of greater than 40° C. Advantageous examples of this second comonomer kind are vinylaromatics (including partly or fully hydrogenated versions), methyl methacrylate, cyclohexyl methacrylate, isobornyl methacrylate and isobornyl acrylate. In this embodiment, the molar weights can be reduced further, and so may favourably even be below 200 000 g/mol.

Particularly preferred examples are styrene and α-methylstyrene, with this enumeration making no claim to completeness.

With further preference, the copolymer or copolymers is or are block, star and/or graft copolymers which contain at least one kind of first polymer block (“soft block”) having a softening temperature of less than −20° C. and at least one kind of a second polymer block (“hard block”) having a softening temperature of greater than +40° C.

The soft block here is preferably apolar in construction and preferably comprises butylene or isobutylene as homopolymer block or copolymer block, the latter preferably copolymerized with itself or with one another or with further comonomers, more preferably apolar comonomers. Examples of suitable apolar comonomers are (partly) hydrogenated polybutadiene, (partly) hydrogenated polyisoprene and/or polyolefins.

The hard block is preferably constructed from vinylaromatics (including partly or fully hydrogenated versions), methyl methacrylate, cyclohexyl methacrylate, isobornyl methacrylate and/or isobornyl acrylate. Particularly preferred examples are styrene and α-methylstyrene, this enumeration making no claim to completeness. The hard block thus comprises the at least one comonomer kind which—viewed as hypothetical homopolymer—has a softening temperature of greater than 40° C.

In one particularly advantageous embodiment, the preferred soft blocks and hard blocks described are actualized simultaneously in the copolymer or copolymers.

It is advantageous if the at least one block copolymer is a triblock copolymer constructed from two terminal hard blocks and one middle soft block. Diblock copolymers are likewise highly suitable, as are mixtures of triblock and diblock copolymers.

It is very preferred to use triblock copolymers of the polystyrene-block-polyisobutylene-block-polystyrene type. Systems of this kind have been disclosed under the names SIBStar from Kaneka and Oppanol IBS from BASF. Other systems which can be used advantageously are described in EP 1 743 928 A1.

The fact that the copolymers include a fraction of isobutylene or butylene as at least one comonomer kind results in an apolar adhesive which offers advantageously low volume barrier properties especially with respect to water vapour.

The low molar masses of the copolymers, in contrast to, for example, polyisobutylene homopolymers, permit good processing properties for the producer, especially in formulating and coating operations. Low molar mass leads to better and faster solubility, if solvent-based operations are desired (for isobutylene polymers and butylene polymers particularly, the selection of suitable solvents is small). Moreover, higher copolymer concentrations in the solution are possible. In solvent-free operations as well, an inventively low molar mass proves to be an advantage, since the melt viscosity is lower than with comparative systems of higher molar mass, even if the latter are not preferred within the meaning of this invention.

Merely reducing the molar mass does lead, of course, to better solubility and lower solution and melt viscosities. However, with the lower molar mass, there is detriment to other properties important from a performance standpoint, such as the cohesion of an adhesive, for example. Here, the inventive use of the at least second comonomer kind, with the softening temperature, for a hypothetical homopolymer, of more than 40° C., is an effective counter.

Where homopolymers such as, in particular, polybutylene or polyisobutylene are employed, mixtures of homopolymers are appropriate, consisting of a homopolymer of relatively high molar weight for adjusting the cohesion (appropriate here are molar weights of between 200 000 g/ml and 1 000 000 g/mol), and of a homopolymer of relatively low molar weight, for adjusting the flow-on behaviour (appropriate here are molar masses below 200 000 g/mol).

The fraction of (co)polymer in the adhesive formula is preferably at least 20 wt % and at most 60 wt %, more preferably at least 30 wt % and at most 50 wt %.

The requisite barrier properties can be realized by the at least one (co)polymer. The (co)polymer also acts as a film former, allowing the curable formulation to be prefabricated as an adhesive layer in adhesive tapes, including, for example, in the form of adhesive transfer tape, in any desired dimensions. Furthermore, the cured formulation also acquires flexibility/bendability by virtue of the (co)polymer, these qualities being desired for numerous (opto-)electronic assemblies.

The adhesive of the invention comprises at least one kind of an at least partly hydrogenated tackifier resin, advantageously of the sort which are compatible with the copolymer or, where a copolymer constructed from hard blocks and soft blocks is used, compatible primarily with the soft block (soft resins).

It is advantageous if this tackifier resin has a tackifier resin softening temperature (test C) of greater than 25° C., preferably greater than 80° C. It is advantageous, furthermore, if additionally at least one kind of tackifier resin having a tackifier resin softening temperature of less than 20° C. is used. In this way it is possible, if necessary, to fine-tune not only the technical bonding behaviour but also the flow behaviour on the bonding substrate.

Resins in the PSA which may be used are hydrocarbon resins, in particular hydrogenated polymers of dicyclopentadiene, partially, selectively or fully hydrogenated hydrocarbon resins based on C₅, C₅/C₉ or C₉ monomer streams, polyterpene resins based on α-pinene and/or β-pinene and/or δ-limonene, and hydrogenated polymers of preferably pure C₈ and C₉ aromatics. Aforementioned tackifier resins may be used either alone or in a mixture.

It is possible here to use both room-temperature-solid resins and liquid resins. In order to ensure high aging stability and UV stability, hydrogenated resins with a degree of hydrogenation of at least 90%, preferably of at least 95%, are preferred. The tackifier resin or resins are at least partially compatible with the isobutylene- or butylene-containing (co)polymer segments.

Preference is given, accordingly, to apolar resins having a DACP (diacetone alcohol cloud point) of more than 30° C. and an MMAP (mixed methylcylohexane aniline point) of greater than 50° C., more particularly having a DACP of more than 37° C. and an MMAP of greater than 60° C. The DACP and the MMAP each indicate the solubility in a particular solvent (test D). Through the selection of these ranges, the permeation barrier achieved, especially with respect to water vapour, is particularly high. Moreover, the desired compatibility is produced with the isobutylene- or butylene-containing (co)polymer segments.

The fraction of tackifier resin(s) in the adhesive formula is preferably at least 20 wt % and at most 60 wt %, more preferably at least 30 wt % and at most 40 wt %.

The adhesive of the invention further comprises at least one kind of a reactive resin based on a cyclic ether, for thermal crosslinking, having a softening temperature in thee uncured state of less than 40° C., preferably of less than 20° C.

The reactive resins based on cyclic ethers are more particularly epoxides, i.e. compounds which carry at least one oxirane group, or oxetanes. They may be aromatic or more particularly aliphatic or cycloaliphatic in nature.

Reactive resins that can be used may be monofunctional, difunctional, trifunctional, tetrafunctional or of higher functionality up to polyfunctional, where the functionality relates to the cyclic ether group.

Examples, without any intention to impose a restriction, are 3,4-epoxycyclohexylmethyl 3′,4′-epoxycyclohexanecarboxylate (EEC) and derivatives, dicyclopentadiene dioxide and derivatives, 3-ethyl-3-oxetanemethanol and derivatives, diglycidyl tetrahydrophthalate and derivatives, diglycidyl hexahydrophthalate and derivatives, 1,2-ethanediol diglycidyl ether and derivatives, 1,3-propanediol diglycidyl ether and derivatives, 1,4-butanediol diglycidyl ether and derivatives, higher 1,n-alkanediol diglycidyl ethers and derivatives, bis[(3,4-epoxycyclohexyl)methyl] adipate and derivatives, vinylcyclohexyl dioxide and derivatives, 1,4-cyclohexanedimethanol bis(3,4-epoxycyclohexanecarboxylate) and derivatives, diglycidyl 4,5-epoxytetrahydrophthalate and derivatives, bis[1-ethyl(3-oxetanyl)methyl] ether and derivatives, pentaerythrityl tetraglycidyl ether and derivatives, bisphenol A diglycidyl ether (DGEBA), hydrogenated bisphenol A diglycidyl ether, bisphenol F diglycidyl ether, hydrogenated bisphenol F diglycidyl ether, epoxyphenol novolaks, hydrogenated epoxyphenol novolaks, epoxycresol novolaks, hydrogenated epoxycresol novolaks, 2-(7-oxabicyclospiro(1,3-dioxane-5,3′-(7-oxabicyclo[4.1.0]heptane)), 1,4-bis((2,3-epoxypropoxy)-methyl)cyclohexane.

Reactive resins can be used in their monomeric form or else dimeric form, trimeric form, etc., up to and including their oligomeric form.

Compounds according to WO 2013/156509 A2 can be used as reactive resins likewise for the purpose of this invention.

Mixtures of reactive resins with one another, but also with other coreactive compounds such as alcohols (monofunctional or polyfunctional) or vinyl ethers (monofunctional or polyfunctional) are likewise possible.

The fraction of reactive resin(s) in the adhesive formula is at least 20 wt % and at most 50 wt %, preferably at least 25 wt % and at most 40 wt %.

The adhesive formulation additionally comprises at least one kind of latent-reactive thermally activatable initiator for the cationic curing of the reactive resins.

The selection of suitable latent-reactive thermal initiators for the cationic curing of the reactive resins in relation to the present object represents a particular challenge. As already observed, the temperature needed in order to activate the latent-reactive thermal initiator must be situated within a range in which the article to be sealed—that is, in particular, the sensitive (opto-)electronic element, still has sufficient thermal stability. The activation temperature (Test J) ought therefore to be no higher than 125° C., and preferably indeed no higher than 100° C. On the other hand, the desire is for high stability under customary storage/transport conditions (“latency”), in other words lack of reactivity within a defined temperature range, such as below 40° C., for example. A further factor hindering the selection of suitable systems is the fact that for many applications there are exacting requirements imposed on the optical quality of the adhesive product and of the bonded assembly. The adhesive products must therefore already be of high optical quality. This can usually be achieved only by means of solvent-based coatings of the adhesive formulation. Within the temperature range of the drying process for the solvent-containing coating, therefore, as well, the latent-reactive thermally activatable initiator for the cationic curing must be stable. This means typically latency (Test K) in the temperature range below 60° C., preferably below 70° C.

A series of thermally activatable initiators for cationic curing of, for example, epoxides have been described in the past. In this connection, the term “(curing) catalyst” is often also used instead of initiator. A multiplicity of common curing systems for epoxides, however, are not suitable for the purposes of the present invention. They include BF₃.amine complexes, anhydrides, imidazoles, amines, DICY, dialkylphenylacylsulphonium salts, triphenylbenzylphosphonium salts, and amine-blocked phenylsulphonium acids. With these curing systems, the activation energy required is too high, and/or the latency in the storage state of the adhesive system is not sufficient. In some cases, moreover, the requirements of a high transparency, low haze and low yellowing tendency are not realizable.

Thermally activatable initiators which can be used for purposes of the present invention for catalytic curing of epoxides are, in particular, pyridinium salts, ammonium salts (especially anilinium salts) and sulphonium salts (especially thiolanium) salts and also lanthanoid triflates.

Very advantageous are N-benzylpyridinium salts and benzylpyridinium salts, in which case aromatic structures may be substituted, for example, by alkyl, alkoxy, halogen or cyano groups.

J. Polym. Sci. A, 1995, 33, 505ff, US 2014/0367670 A1, U.S. Pat. No. 5,242,715, J. Polym. Sci. B, 2001, 39, 2397ff, EP 393893 A1, Macromolecules, 1990, 23, 431ff, Macromolecules, 1991, 24, 2689, Macromol. Chem. Phys., 2001, 202, 2554ff, WO 2013/156509 A2 and JP 2014/062057 A1, identify corresponding compounds which can be used for the purposes of this invention.

Examples of compounds which can be used very advantageously among the initiator systems available commercially include San-Aid SI 80 L, San-Aid SI 100 L, San-Aid SI 110 L from Sanshin, Opton CP-66 and Opton CP-77 from Adeka and K-Pure TAG 2678, K-Pure CXC 1612 and K-Pure CXC 1614 from King Industries.

Employable very advantageously are, moreover, lanthanoid triflates (samarium(III) triflate, ytterbium(III) triflate, erbium(III) triflate, dysprosium(III) triflate) are available from Sigma Aldrich and Alfa Aesar (lanthanum(III) triflate).

Suitable anions for the initiators which can be used include hexafluoroantimonate, hexafluorophosphate, hexafluoroarsenate, tetrafluoroborate and tetra(penta-fluorophenyl)borate. Other anions which can be employed are those according to JP 2012-056915 A1 and EP 393893 A1.

The skilled person is aware of further systems which can likewise be employed in accordance with the invention. Latent-reactive thermally activatable initiators for cationic curing are used in uncombined form or as a combination of two or more thermally curable initiators.

The fraction of thermally activatable initiators for the cationic curing in relation to the amount of reactive resin employed is preferably at least 0.3 wt % and at most 2.5 wt %, more preferably at least 0.5 wt % and at most 1.5 wt %.

Relative to photoinitiators and photoinitiatable curing systems, thermally activatable initiators and curing systems have the advantages that the adhesive tape is easier to transport and process. There is no need to observe exclusion of light. Furthermore, UV light which is needed for the curing of adhesive assembly represents potential damage to certain sensitive (opto-)electronic elements.

Advantageous for the purposes of the present invention are latent-reactive thermally activatable initiators which have activation temperature of at least 60° C. and at most 125° C., preferably of at least 70° C. and at most 100° C., at which cationic curing of the reactive resins can be initiated. The cure time in this case may be 15 minutes or more and 2 hours or less, although even shorter or even longer curing times are not excluded.

The PSA is preferably partly crosslinked or crosslinked to completion only after application, on the electronic arrangement. The conversion rate in the reactive resin curing, relative to the reactive groups in the reactive-resin molecules, is typically not 100%. It may in particular be between 20% and 90% or between 40% and 80%.

The adhesive may have customary adjuvants added, such as ageing inhibitors (antiozonants, antioxidants, light stabilizers, etc.).

Additives for the adhesive that are typically utilized are as follows:
plasticizers such as, for example, plasticizer oils or low molecular mass liquid polymers such as, for example, low molecular mass polybutenes
primary antioxidants such as, for example, sterically hindered phenols
secondary antioxidants such as, for example, phosphites or thioethers
process stabilizers such as, for example, C radical scavengers
light stabilizers such as, for example, UV absorbers or sterically hindered amines
processing assistants
wetting additives
adhesion promoters
endblock reinforcer resins and/or
optionally further polymers, preferably elastomeric in nature; elastomers which can be utilized accordingly include, among others, those based on pure hydrocarbons, examples being unsaturated polydienes such as natural or synthetically produced polyisoprene or polybutadiene, elastomers with substantial chemical saturation, such as, for example, saturated ethylene-propylene copolymers, α-olefin copolymers, ethylene-propylene rubber, and also chemically functionalized hydrocarbons such as, for example, halogen-containing, acrylate-containing, allyl ether-containing or vinyl ether-containing polyolefins.

The adjuvants or additives are not mandatory; the adhesive also works without their addition, individually or in any desired combination. They are preferably selected in such a way that they do no substantially colour or terbidify the adhesive.

Fillers can be used advantageously in the PSAs of the invention. As fillers in the adhesive it is preferred to use nanoscale and/or transparent fillers. In the present context a filler is termed nanoscale if in at least one dimension it has a maximum extent of about 100 nm, preferably about 10 nm. Particular preference is given to using those fillers which are transparent in the adhesive and have a platelet-shaped crystallite structure and a high aspect ratio with homogeneous distribution. The fillers with a platelet-like crystallite structure and with aspect ratios of well above 100 generally have a thickness of only a few nm, but the length and/or width of the crystallites may be up to several μm. Fillers of this kind are likewise referred to as nanoparticles. The particulate architecture of the fillers with small dimensions, moreover, is particularly advantageous for a transparent embodiment of the PSA.

Through the construction of labyrinthine structures by means of the fillers described above in the adhesive matrix, the diffusion pathway for, for example, oxygen and water vapour is extended in such a way that their permeation through the layer of adhesive is lessened. For improved dispersibility of these fillers in the binder matrix, these fillers may be surface-modified with organic compounds. The use of such fillers per se is known from US 2007/0135552 A1 and from WO 02/026908 A1, for example.

In another advantageous embodiment of the present invention, use is also made of fillers which are able to interact in a particular way with oxygen and/or water vapour. Water vapour or oxygen penetrating into the (opto)electronic arrangement is then chemically or physically bound to these fillers. These fillers are also referred to as getters, scavengers, desiccants or absorbers. Such fillers include by way of example, but without restriction, the following: oxdizable metals, halides, salts, silicates, oxides, hydroxides, sulphates, sulphites, carbonates of metals and transition metals, perchlorates and activated carbon, including its modifications. Examples are cobalt chloride, calcium chloride, calcium bromide, lithium chloride, zinc chloride, zinc bromide, silicon dioxide (silica gel), aluminium oxide (activated aluminium), calcium sulphate, copper sulphate, sodium dithionite, sodium carbonate, magnesium carbonate, titanium dioxide, bentonite, montmorillonite, diatomaceous earth, zeolites and oxides of alkali metals and alkaline earth metals, such as barium oxide, calcium oxide, iron oxide and magnesium oxide, or else carbon nanotubes. Additionally it is also possible to use organic absorbers, examples being polyolefin copolymers, polyamide copolymers, PET copolyesters or other absorbers based on hybrid polymers, which are used generally in combination with catalysts such as cobalt, for example. Further organic absorbers are, for instance, polyacrylic acid with a low degree of crosslinking, ascorbates, glucose, gallic acid or unsaturated fats and oils.

In order to maximize the activity of the fillers in terms of the barrier effect, their fraction should not be too small. The fraction is preferably at least 5%, more preferably at least 10% and very preferably at least 15% by weight. Typically as high as possible a fraction of fillers is employed, without excessively lowering the bond strengths of the adhesive or adversely affecting other properties. Depending on the type of fillers, filler fractions of more than 40% to 70% by weight may be reached.

Also advantageous is a very fine division and very high surface area on the part of the fillers. This allows a greater efficiency and a higher loading capacity, and is achieved in particular using nanoscale fillers.

The fillers are not mandatory; the adhesive also operates without the addition thereof individually or in any desired combination.

With further preference an adhesive is employed which in certain embodiments is transparent in the visible light of the spectrum (wavelength range from about 400 nm to 800 nm). The desired transparency can be achieved in particular through the use of colourless tackifier resins and by adjusting the compatibility of copolymer (in microphase-separated systems such as block copolymers and graft copolymers, with their soft block) and tackifier resin, but also with the reactive resin. Reactive resins are for this purpose selected advantageously from aliphatic and cycloaliphatic systems. A PSA of this kind is therefore also particularly suitable for full-area use over an (opto)electronic structure. Full-area bonding, in the case of an approximately central disposition of the electronic structure, offers the advantage over edge sealing that the permeate would have to diffuse through the entire area before reaching the structure. The permeation pathway is therefore significantly increased. The prolonged permeation pathways in this embodiment, in comparison to edge sealing by means of liquid adhesives, for instance, have positive consequences for the overall barrier, since the permeation pathway is in inverse proportion to the permeability.

“Transparency” here denotes an average transmittance (Test E) of the adhesive in the visible range of light of at least 75%, preferably higher than 90%, this consideration being based on uncorrected transmission, in other words without subtracting losses through interfacial reflection. These values relate to the cured adhesive.

The adhesive preferably exhibits a haze (Test F) of less than 5.0%, preferably less than 2.5%. These values relate to the cured adhesive.

There are many applications within the (opto-)electronic sphere where it is necessary that the adhesive formulation exhibits hardly any yellowing or none at all. This can be quantified by way of the Δb* (Test G) of the CIE Lab system. The Δb* is between 0 and +3.0, preferably between 0 and +1.5, very preferably between 0 and +1.0. These figures are based on the cured adhesive.

The pressure-sensitive adhesive is prepared and processed very preferably from solution. In that case a solvent (mixture) is employed which can be removed by drying at a temperature below the activation temperature of the latent-reactive thermally activatable initiator. Very advantageous solvents are those which, even in mixtures, have a boiling point under ambient pressure (standard pressure may be assumed here) of not more than 100° C., preferably of not more than 80° C., very preferably of not more than 65° C.

As part of the production process, the constituents of the pressure-sensitive adhesive are dissolved in a suitable solvent, for example an alkane or cycloalkane or mixtures of alkane, cycloalkane and ketone, and are applied to the carrier by methods that are general knowledge. In the case of processes from solution, coating operations with doctors, knives, rolls or nozzles are known, to name but a few. The skilled person is familiar with the operational parameters for obtaining transparent adhesive layers. In solvent coating operations, the coating outcome can be influenced by the selection of the solvent or solvent mixture. Here again the skilled person is well aware how to select suitable solvents. Combinations of, in particular, apolar solvents which boil below 100° C. with solvents which boil above 100° C., especially aromatic solvents, are likewise conceivable. Since the drying properties of solvents are dependent not only on their boiling temperature, it is also possible in principle to use mixtures with solvents having boiling temperatures above 100° C. such as toluene, for example, if a drying operation is utilized that operates for sufficient solvent elimination with drying temperatures below the activation temperature of the latent-reactive thermally activatable initiator.

The adhesive of the invention can be used with particular advantage in a single-sided or double-sided adhesive tape. This mode of presentation permits particularly simple and uniform application of the adhesive.

The general expression “adhesive tape” encompasses a carrier material which is provided on one or both sides with a (pressure-sensitive) adhesive. The carrier material encompasses all sheetlike structures, examples being two-dimensionally extended films or film sections, tapes with an extended length and limited width, tape sections, diecuts (in the form of edge surrounds or borders of an (opto)electronic arrangement, for example), multi-layer arrangements, and the like. For different applications it is possible to combine a very wide variety of different carriers, such as, for example, films, woven fabrics, nonwovens and papers, with the adhesives. Furthermore, the expression “adhesive tape” also encompasses what are called “adhesive transfer tapes”, i.e. an adhesive tape without carrier. In the case of an adhesive transfer tape, the adhesive is instead applied prior to application between flexible liners which are provided with a release coat and/or have anti-adhesive properties. For application, generally, first one liner is removed, the adhesive is applied, and then the second liner is removed. The adhesive can thus be used directly to join two surfaces in (opto)electronic arrangements.

Also possible, however, are adhesive tapes which operate not with two liners, but instead with a single liner with double-sided release. In that case the web of adhesive tape is lined on its top face with one side of a double-sidedly releasing liner, while its bottom face is lined with the reverse side of the double-sidedly releasing liner, more particularly of an adjacent turn in a bale or roll.

As the carrier material of an adhesive tape it is preferred in the present case to use polymer films, film composites, or films or film composites that have been provided with organic and/or inorganic layers. Such films/film composites may be composed of any common plastics used for film manufacture, examples though without restriction—including the following:
polyethylene, polypropylene—especially the oriented polypropylene (OPP) produced by monoaxial or biaxial stretching, cyclic olefin copolymers (COC), polyvinyl chloride (PVC), polyesters—especially polyethylene terephthalate (PET) and polyethylene naphthalate (PEN), ethylene-vinyl alcohol (EVOH), polyvinylidene chloride (PVDC), polyvinylidene fluoride (PVDF), polyacrylonitrile (PAN), polycarbonate (PC), polyamide (PA), polyethersulphone (PES) or polyimide (PI).

The carrier, moreover, may be combined with organic or inorganic coatings or layers. This can be done by customary techniques, such as surface coating, printing, vapour coating, sputtering, coextruding or laminating, for example. Examples though without restriction here include, for instance, oxides or nitrides of silicon and of aluminium, indium-tin oxide (ITO) or sol-gel coatings.

Also very good as carrier films are those made from thin glass. They are available in layer thicknesses of less than 1 mm and even in 30 μμm, for example, D 263 T from Schott or Willow Glass from Corning. Thin glass films can be stabilized further by laminating them with a polymeric film (polyester, for example) by means of an adhesive transfer tape, if desired.

Preferred thin glasses used are those carrier materials or other types of carrier materials having a thickness of 15 to 200 μm, preferably 20 to 100 μm, more preferably 25 to 75, very preferably 30 to 50 μm.

It is advantageous to use for thin glasses a borosilicate glass such as D263 T eco from Schott, an alkali metal-alkaline earth metal-silicate glass or an aluminoborosilicate glass such as AF 32 eco, again from Schott. An alkali-free thin glass such as AF32 eco is advantageous because the UV transmission is higher.

An alkali-containing thin glass such as D263 T eco is advantageous because the coefficient of thermal expansion is higher and matches more closely with the polymeric constituents of the further OLED construction. Glasses of these kinds may be produced in a down-draw process, as referenced in WO 00/41978 A1, or produced in processes of the kind disclosed in EP 1 832 558 A1, for example. WO 00/41978 A1 further discloses processes for producing composites of thin glass and polymer layers or polymer films.

With particular preference, these films/film composites, especially the polymer films, are provided with a permeation barrier for oxygen and water vapour, the permeation barrier exceeding the requirements for the packaging sector (WVTR<10⁻¹ g/(m²d) and OTR<10⁻¹ cm³/(m²d bar) according to Test H).

In the case of thin glass films or thin glass film composites, no such coating is needed, owing to the intrinsically high barrier properties of the glass.

Thin glass films or thin glass film composites are preferably as is generally the case for polymer films too—provided in the form of tape from a roll. Corresponding glasses are available already from Corning under the Willow Glass name. This supply form can be laminated outstandingly with an adhesive preferably likewise provided in tape form.

Moreover, the films/film composites, in a preferred embodiment, may be transparent, so that the total construction of an adhesive article of this kind is also transparent. Here again, “transparency” means an average transmittance in the visible region of light of at least 75%, preferably higher than 90%.

In the case of double-sidedly (self-)adhesive tapes, the adhesives used as the top and bottom layer may be identical or different adhesives of the invention, and/or the layer thicknesses thereof that are used may be the same or different. The carrier in this case may have been pretreated according to the prior art on one or both sides, with the achievement, for example, of an improvement in adhesive anchorage. It is also possible for one or both sides to have been furnished with a functional layer which is able to function, for example, as a shutout layer. The layers of PSA may optionally be lined with release papers or release films. Alternatively it is also possible for only one layer of adhesive to be lined with a double-sidedly releasing liner.

In one version, an adhesive of the invention is provided in the double-sidedly (self-)adhesive tape, and also any desired further adhesive is provided, for example one which adheres particularly well to a masking substrate or exhibits particularly good repositionability.

Furthermore, the adhesive and also any adhesive tape formed using it are outstandingly suitable for the encapsulation of an electronic arrangement with respect to permeates, with the adhesive or adhesive tape being applied on and/or around the regions of the electronic arrangement that are to be encapsulated.

Encapsulation in the present case refers not only to complete enclosure with the stated PSA but also even application of the PSA to some of the regions to be encapsulated in the (opto)electronic arrangement: for example, a single-sided coverage or the enframing of an electronic structure.

With adhesive tapes it is possible in principle to carry out two types of encapsulation. Either the adhesive tape is diecut beforehand and bonded only around the regions that are to be encapsulated, or it is adhered by its full area over the regions that are to be encapsulated. An advantage of the second version is the easier operation and the frequently better protection.

The present invention is based first on the finding that in spite of the above-described disadvantages it is possible to use a (pressure-sensitive) adhesive for encapsulating an electronic arrangement, with the disadvantages described above in relation to PSAs occurring not at all or only to a reduced extent. It has been found, in fact, that an adhesive based on a (co)polymer comprising at least isobutylene or butylene as comonomer kind and, optionally but preferably, at least one comonomer kind which viewed as a hypothetical homopolymer has a softening temperature of greater than 40° C. is especially suitable for encapsulating electronic arrangements.

The adhesive preferably being a PSA, application is particularly simple, since there is no need for preliminary fixing. PSAs permit flexible and clean processing. As a result of presentation in the form of a pressure-sensitive adhesive tape, it is also possible to meter easily the amount of the PSA, and there are not any solvent emissions either. At least after application to the target substrate or the target substrates, the PSA is subjected to crosslinking by thermal activation of the latent reactive initiator. This process procedure is likewise preferred.

An advantage of the present invention, then, in comparison to other PSAs, is the combination of very good barrier properties with respect to oxygen and especially to water vapour, in conjunction with good interfacial adhesion to different substrates, good cohesive properties and, by comparison with liquid adhesives, very high flexibility and ease of application in the (opto)electronic arrangement and on/in the encapsulation. In certain embodiments, furthermore, there are also highly transparent adhesives that can be used particularly for deployment in (opto)electronic arrangements, since the attenuation of incident or emergent light is kept very low.

Encapsulation by lamination of at least parts of the (opto)electronic constructions with a sheetlike barrier material (e.g. glass, more particularly thin glass, metal oxide-coated films, metallic foils, multilayer substrate materials) can be achieved with a very good barrier effect in a simple roll-to-roll process. The flexibility of the overall construction is dependent not only on the flexibility of the PSA but also on further factors, such as geometry and thickness of the (opto)electronic constructions and/or of the sheetlike barrier materials. The high flexibility of the PSA, however, allows realization of very thin, pliable and flexible (opto)electronic constructions.

In summary, the adhesive of the invention meets all of the requirements imposed on an adhesive used for encapsulating an (opto)electronic arrangement:
low volume permeation of water vapour and oxygen in the cured state, as manifested in a WVTR (Mocon) of less than 12 g/m² d, and an OTR (Mocon) of less than 1000 cm³/m²*d*bar,
optional, but preferably high transparency, with a transmittance of preferably more than 90%;
optional, but preferably a haze of less than 5.0%, preferably less than 2.5%;
a Δb* of between 0 and +3.0, preferably between 0 and +1.5, very preferably between 0 and +1.0;
high bond strength for the cured system on glass of more than 1.5 N/cm, preferably more than 2.5 N/cm² (test I).

Further details, objectives, features and advantages of the present invention are elucidated in more detail below with reference to a number of figures which show preferred exemplary embodiments:

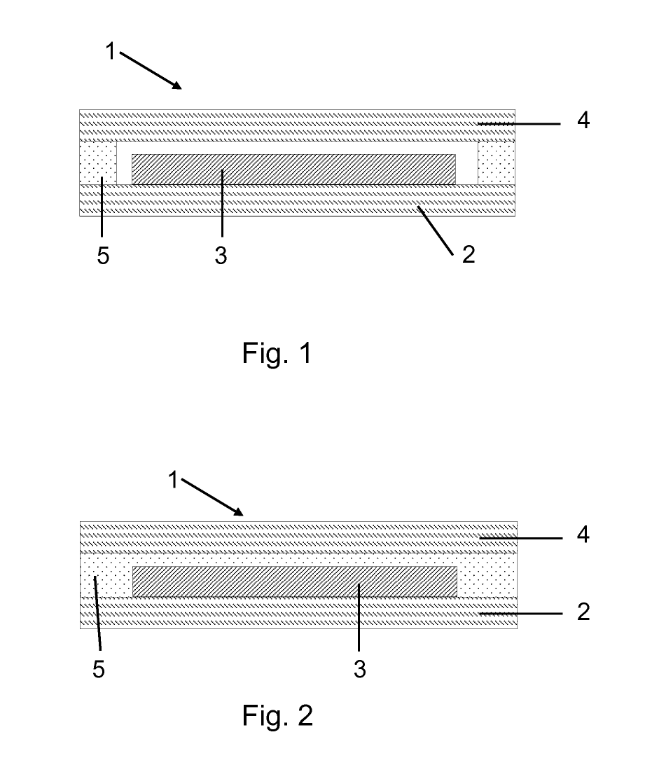

FIG. 1 shows a first (opto)electronic arrangement in a diagrammatic representation,

FIG. 2 shows a second (opto)electronic arrangement in a diagrammatic representation,

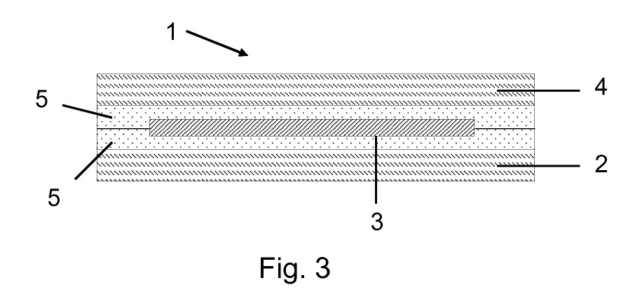

FIG. 3 shows a third (opto)electronic arrangement in a diagrammatic representation.

FIG. 1 shows a first embodiment of an (opto)electronic arrangement 1. This arrangement 1 has a substrate 2 on which an electronic structure 3 is disposed. Substrate 2 itself is designed as a barrier for permeates and thus forms part of the encapsulation of the electronic structure 3. Disposed above the electronic structure 3, in the present case also at a distance from it, is a further cover 4 designed as a barrier.

In order to encapsulate the electronic structure 3 to the side as well and at the same time to join the cover 4 to the electronic arrangement 1 in its remaining part, a pressure-sensitive adhesive (PSA) 5 runs round adjacent to the electronic structure 3 on the substrate 2. In other embodiments the encapsulation is accomplished not with a pure PSA 5, but instead with an adhesive tape 5 which comprises at least one PSA of the invention. The PSA 5 joins the cover 4 to the substrate 2. By means of an appropriately thick embodiment, moreover, the PSA 5 allows the cover 4 to be distanced from the electronic structure 3.

The PSA 5 is of a kind based on the PSA of the invention as described above in general form and set out in more detail below in exemplary embodiments. In the present case, the PSA 5 not only takes on the function of joining the substrate 2 to the cover 4 but also, furthermore, provides a barrier layer for permeates, in order thus to encapsulate the electronic structure 3 from the side as well with respect to permeates such as water vapour and oxygen.

In the present case, furthermore, the PSA 5 is provided in the form of a diecut comprising a double-sided adhesive tape. A diecut of this kind permits particularly simple application.

FIG. 2 shows an alternative embodiment of an (opto)electronic arrangement 1. Shown, again, is an electronic structure 3 which is disposed on a substrate 2 and is encapsulated by the substrate 2 from below. Above and to the side of the electronic structure, the PSA 5 is now in a full-area disposition. The electronic structure 3 is therefore encapsulated fully from above by the PSA 5. A cover 4 is then applied to the PSA 5. This cover 4, in contrast to the previous embodiment, need not necessarily fulfill the high barrier requirements, since the barrier is provided by the PSA itself. The cover 4 may merely, for example, take on a mechanical protection function, or else may also be provided as a permeation barrier.

FIG. 3 shows a further alternative embodiment of an (opto)electronic arrangement 1. In contrast to the previous embodiments, there are now two PSAs 5a, 5b, which in the present case are identical in configuration. The first PSA 5a is disposed over the full area of the substrate 2. The electronic structure 3 is provided on the PSA 5a, and is fixed by the PSA 5a. The assembly comprising PSA 5a and electronic structure 3 is then covered over its full area with the other PSA, 5b, with the result that the electronic structure 3 is encapsulated on all sides by the PSAs 5a, b. Provided above the PSA 5b, in turn, is the cover 4.

In this embodiment, therefore, neither the substrate 2 nor the cover 4 need necessarily have barrier properties. Nevertheless, they may also be provided, in order to restrict further the permeation of permeates to the electronic structure 3.

In relation to FIGS. 2, 3 in particular it is noted that in the present case these are diagrammatic representations. From the representations it is not apparent in particular that the PSA 5, here and preferably in each case, is applied with a homogeneous layer thickness. At the transition to the electronic structure, therefore, there is not a sharp edge, as it appears in the representation, but instead the transition is fluid and it is possible instead for small unfilled or gas-filled regions to remain. If desired, however, there may also be conformation to the substrate, particularly when application is carried out under vacuum or under increased pressure. Moreover, the PSA is compressed to different extents locally, and so, as a result of flow processes, there may be a certain compensation of the difference in height of the edge structures. The dimensions shown are also not to scale, but instead serve rather only for more effective representation. In particular, the electronic structure itself is usually of relatively flat design (often less than 1 μm thick).

In all of the exemplary embodiments shown, the PSA 5 is applied in the form of a pressure-sensitive adhesive tape. This may in principle be a double-sided pressure-sensitive adhesive tape with a carrier, or may be an adhesive transfer tape. In the present case, an adhesive transfer tape embodiment is selected.

The thickness of the PSA, present either as an adhesive transfer tape or as a coating on a sheetlike structure, is preferably between about 1 μm and about 150 μm, more preferably between about 5 μm and about 75 μm, and very preferably between about 12 μm and 50 μm. High layer thicknesses between 50 μm and 150 μm are employed when the aim is to achieve improved adhesion to the substrate and/or a damping effect within the (opto)electronic construction. A disadvantage here, however, is the increased permeation cross section. Low layer thicknesses between 1 μm and 12 μm reduce the permeation cross section, and hence the lateral permeation and the overall thickness of the (opto)electronic construction. However, there is a reduction in the adhesion on the substrate. In the particularly preferred thickness ranges, there is a good compromise between a low thickness of composition and the consequent low permeation cross section, which reduces the lateral permeation, and a sufficiently thick film of composition to produce a sufficiently adhering bond. The optimum thickness is dependent on the (opto)electronic construction, on the end application, on the nature of the embodiment of the PSA, and, possibly, on the sheetlike substrate.

For double-sided adhesive tapes it is likewise the case, for the barrier adhesive or adhesives, that the thickness of the individual layer or layers of PSA is preferably between about 1 μm and about 150 μm, more preferably between about 5 μm and about 75 μm, and very preferably between about 12 μm and 50 μm. If a further barrier adhesive is used in double-sided adhesive tapes as well as an inventive barrier adhesive, then it may also be advantageous for the thickness of said further barrier adhesive to be more than 150 μm.

A suitable method for bonding the adhesive products with the pressure-sensitive adhesives of the invention comprises the freeing of the first adhesive surface from a protective liner layer, and the laminating of the adhesive product to a first target substrate. This may be done by using (rubber) rollers for lamination, or else in presses. The pressure-sensitive adhesiveness means that particularly high pressure during laminating is not required in every case. A preliminary assembly is obtained. Subsequently, the second adhesive surface as well is freed from the protective liner layer and married to the second target substrate. This as well can be done by using (rubber) rollers for lamination or else in presses. The selection of the laminating process is guided by the nature of the preliminary assembly (rigid or flexible) and of the second target substrate (rigid or flexible). Here again, the pressure-sensitive adhesiveness means that a particularly high pressure during lamination is not necessary in every case. In order to cause the assembly to cure, heat must be introduced at a point in time, preferably during and/or after the second laminating step in the sequence indicated above. Introduction of heat may be accomplished by the use of hot press utilized for the lamination, or by means of a heating tunnel, equipped for example with an IR section. Also particularly suitable are thermal chambers and autoclaves. The latter in particular if the assembly is further to be pressurized in order finally to optimize the quality of laminate. In the case of supply of heat, care should be taken to ensure that the temperature is enough to activate the latent-reactive thermally activatable initiator, but that no thermal damage is caused to sensitive component elements. The curing temperatures in the assembly are therefore between 60° C. and 125° C.; in many cases, temperatures between 70° C. and 100° C. are preferred. Although the duration of introduction of heat is dependent on factors including the assembly design and the corresponding heat transitions, it is possible for periods of heat introduction to be up to 60 minutes or even more. Short cycle times are desired or in-line methods are utilized, frequently. Here, short thermal input times are necessary, and may also be well below 60 minutes, including, for example, in the range of a few minutes or even less.

The invention is elucidated in more detail below by means of a number of examples, without thereby wishing to restrict the invention.

### Test Methods

### Test A—Softening Temperature

The softening temperature of copolymers, hard blocks and soft blocks and uncured reactive resins is determined calorimetrically by means of differential scanning calorimetry (DSC) in accordance with DIN 53765:1994-03. Heating curves run with a heating rate of 10 K/min. The specimens are measured in Al crucibles with a perforated lid under a nitrogen atmosphere. The heating curve evaluated is the second curve. In the case of amorphous substances, there are glass transition temperatures; in the case of (semi-)crystalline substances, there are melting temperatures. A glass transition can be seen as a step in the thermogram. The glass transition temperature is evaluated as the middle point of this step. A melting temperature can be recognized as a peak in the thermogram. The melting temperature recorded is the temperature at which maximum heat change occurs.

### Test B—Molecular Weight

The average molecular weight M_{w} (weight average)—also referred to as molar mass—is determined by means of gel permeation chromatography (GPC). The eluent used is THF with 0.1% by volume trifluoroacetic acid. Measurement takes place at 25° C. The preliminary column used is PSS-SDV, 5 μm, 10³ Å, ID 8.0 mm×50 mm. Separation was carried out using the columns PSS-SDV, 5 μm, 10³ Å, 10⁵ Å and 10⁶ Å, each with an ID of 8.0 mm×300 mm. The sample concentration is 4 g/I, the flow rate 1.0 ml per minute. Measurement takes place against PS standards.

### Test C—Tackifier Resin Softening Temperature

The tackifier resin softening temperature is conducted according to the relevant methodology, which is known as ring and ball and is standardized according to ASTM E28.

The tackifier resin softening temperature of the resins is determined using an automatic ring & ball tester HRB 754 from Herzog. Resin specimens are first finely mortared. The resulting powder is introduced into a brass cylinder with a base aperture (internal diameter at the top part of the cylinder 20 mm, diameter of the base aperture in the cylinder 16 mm, height of the cylinder 6 mm) and melted on a hotplate. The amount introduced is selected such that the resin after melting fully fills the cylinder without protruding.

The resulting sample body, complete with cylinder, is inserted into the sample mount of the HRB 754. Glycerin is used to fill the heating bath where the tackifier resin softening temperature lies between 50° C. and 150° C. For lower tackifier resin softening temperatures, it is also possible to operate with a waterbath. The test balls have a diameter of 9.5 mm and weigh 3.5 g. In line with the HRB 754 procedure, the ball is arranged above the sample body in the heating bath and is placed down on the sample body. 25 mm beneath the base of the cylinder is a collecting plate, with a light barrier 2 mm above it. During the measuring procedure, the temperature is raised at 5° C./min. Within the temperature range of the tackifier resin softening temperature, the ball begins to move through the base aperture in the cylinder, until finally coming to rest on the collecting plate. In this position, it is detected by the light barrier, and at this point in time the temperature of the heating bath is recorded. A duplicate determination is conducted. The tackifier resin softening temperature is the average value from the two individual measurements.

### Test D—Resin Compatibility

MMAP is the mixed methylcyclohexane aniline cloud point, and is determined using a modified ASTM C 611 method. Methylcyclohexane is employed for the heptane used in the standard test method. The method uses resin/aniline/methylcyclohexane in a ratio of 1/2/1 (5 g/10 ml/5 ml), and the cloud point is determined by cooling a heated, clear mixture of the three components until full clouding just occurs.

The DACP is the diacetone cloud point, and is determined by cooling a heated solution of 5 g of resin, 5 g of xylene and 5 g of diacetone alcohol to the point at which the solution becomes cloudy.

Regarding the determination of DACP and MMAP, reference is made to C. Donker, PSTC Annual Technical Seminar Proceedings, May 2001, pp. 149-164.

### Test E—Transmittance

The transmittance of the adhesive was determined via the VIS spectrum. The VIS spectrum was recorded on a Kontron UVIKON 923. The wavelength range of the spectrum measured encompasses all wavelengths between 800 nm and 400 nm, with a resolution of 1 nm. A blank channel measurement was carried out over the entire wavelength range, as a reference. For the reporting of the result, the transmittance measurements within the stated range were averaged. There is no correction for interfacial reflection losses.

### Test F—HAZE Measurement

The HAZE value describes the fraction of transmitted light which is scattered forward at large angles by the irradiated sample. The HAZE value hence quantifies material defects in the surface or the structure that disrupt clear transmission.

The method for measuring the Haze value is described in the ASTM D 1003 standard. This standard requires the recording of four transmittance measurements. For each transmittance measurement, the degree of transmittance is calculated. The four transmittances are used to calculate the percentage haze value. The HAZE value is measured using a Haze-gard Dual from Byk-Gardner GmbH.

### Test G—Colour Value Δb*

The procedure is as per DIN 6174, and the colour characteristics are investigated in the CIELab three-dimensional space formed by the three colour parameters L*, a* and b*. This is done using a BYK Gardner spectro-guide instrument, equipped with a D/65° lamp. Within the CIELab system, L* indicates the grey value, a* the colour axis from green to red, and b* the colour axis from blue to yellow. The positive value range for b* indicates the intensity of the yellow colour component. A white ceramic tile with a b* of 1.80 served as reference. This tile also serves as a sample holder, onto which the adhesive layer under test is laminated. Calorimetry takes place on the respective pure adhesive layer at a thickness of 50 μm, after the adhesive layer has been freed from the release liners. Δb* is the difference between the colour value determined for the adhesive film specimen applied to the substrate tile, and the colour value determined for the pure substrate tile.

### Test H—Permeability for Oxygen (OTR) and Water Vapour (WVTR)

The permeability for oxygen (OTR) and water vapour (WVTR) was determined in accordance with DIN 53380 Part 3 and ASTM F-1249, respectively. For this purpose the PSA is applied with a layer thickness of 50 μm to a permeable membrane. The oxygen permeability is measured at 23° C. and a relative humidity of 50% using a Mocon OX-Tran 2/21 instrument. The water vapour permeability is determined at 37.5° C. and a relative humidity of 90%.

### Test I—Bond Strength

The bond strength was determined as follows: The defined substrates used were glass plates (float glass). The bondable sheetlike element under investigation, the back of which was provided with a 50 μm aluminium foil, for stabilization, was cut to a width of 20 mm and a length of about 25 cm, provided with a handling section, and immediately thereafter pressed onto the selected substrate five times, using a 4 kg steel roller with a rate of advance of 10 m/min in each case. Immediately thereafter the above-bonded sheetlike element was peeled from the substrate at an angle of 180° at room temperature and at 300 mm/min, using a tensile testing instrument (from Zwick), and the force required to achieve this was recorded. The measurement (in N/cm) was obtained as the average from three individual measurements. The testing was performed on crosslinked specimens.

### Test J—Activation Temperature

The activation temperature needed for the thermal curing of the cationically curable reactive resins is determined via Differential Scanning calorimetry (DSC). The specimens are subjected to measurement in Al crucibles with perforated lid under nitrogen atmosphere. For the crucible plates to be covered effectively with the sample, the specimen is first heated to 40° C. in the apparatus and cooled again to 25° C. The actual measurement is commenced at 25° C., the heating curve running with a heating rate of 10 K/min. The first heating curve is evaluated. The onset of the thermally initiated curing reaction is recorded by the measuring apparatus in the form of the associated released reaction enthalpy, and is indicated as an exothermic signal (peak) in the thermogram.

The activation temperature used is the temperature of this signal at which the measurement plot begins to deviate from the baseline (as a tool for finding this point, the first derivation of the thermogram may be used; the beginning of the reaction can be associated with the point in the thermogram at which the first derivation of the thermogram adopts an amount of 0.01 mW/(K min); where exothermic signals are shown upwards in the diagram, the sign is positive; where they are shown downwards, the sign is negative). Moreover, a record is made of the integral, standardized in relation to the quantity of specimen weighed out.

### Test K—Latency

The latency of the thermally activatable cationically curable adhesion film, in other words the curing reactions substantially not yet ensuing in a particular temperature range below the desired activation temperature, is tested by means of Differential Scanning Calorimetry (DSC). For this purpose, the specimens are given a special preparation. A coat of adhesive film generated from solution (for composition see examples) is dried in the forced air drying cabinet at 40° C. for 6 hours. The thickness of the dried film was 15 μm. The specimens thus dried are subjected to measurement in Al crucibles with perforated lid under nitrogen atmosphere. For effective coverage of the crucible base by the sample, the specimen is first heated to 40° C. in the instrument and cooled again to 25° C. The actual measurement is commenced at 25° C., with the heating curve running with a heating rate of 10 K/min to the desired temperature at which the curing reaction is substantially not yet to begin, in other words, corresponding to the above embodiment, at 60° C. or 70° C. As soon as this temperature is reached, the sample is left at this temperature for 5 minutes, then cooled to 25° C. (the cooling rate set is −10 K/min). The specimen is left at 25° C. for 5 minutes before subjected to a second heating ramp (heating rate 10 K/min). It is heated to 200° C. and the exothermic signal is analysed, correlating with the course of the curing reaction. A record is made of the activation temperature (see Test J) and of the integral of this signal, standardized for the quantity of specimen weighed out. The results of a specimen section investigated according to Test K are compared with those of a further section of this specimen which was subjected not to Test K but rather to Test J. For the purposes of this invention, the thermally activatable cationically curable system is classed as latent at the temperature studied if the standardized integral according to Test J (corresponding to 100% reactivity) is different by not more than 10%, preferably lower by not more than 5%, than the standardized integral according to Test K, and the activation temperature according to Test J deviates by no more than 5 K, preferably no more than 2 K, from that from Test K.

### Test L—Determination of Lag Time (Lifetime Test)

As a measure for determining the lifetime of an electronic construction, a calcium test was employed. For this purpose, in vacuo, a thin layer of calcium, measuring 10×10 mm², was deposited onto a glass plate and subsequently stored under a nitrogen atmosphere. The thickness of the calcium layer is approximately 100 nm. The calcium layer is encapsulated using an adhesive tape (23×23 mm²) with the adhesive to be tested and a thin glass plate (35 μm, Schott) as support material. For the purpose of stabilization, the thin glass sheet was laminated to a PET film that had a thickness of 100 μm, using an adhesive transfer tape that was 50 μm thick and comprised an acrylate PSA of high optical transparency. The adhesive is applied to the glass plate in such a way that the adhesive covers the calcium mirror with an all-round margin of 6.5 mm (A-A). Owing to the opaque glass carrier the permeation is determined only through the PSA or along the interfaces.

The test is based on the reaction of calcium with water vapour and oxygen, as described, for example, by A. G. Erlat et. al. in “47th Annual Technical Conference Proceedings—Society of Vacuum Coaters”, 2004, pages 654 to 659, and by M. E. Gross et al. in “46th Annual Technical Conference Proceedings Society of Vacuum Coaters”, 2003, pages 89 to 92. The light transmittance of the calcium layer is monitored, and increases as a result of the conversion into calcium hydroxide and calcium oxide. With the test set-up described, this takes place from the margin, and so there is a reduction in the visible area of the calcium mirror. The time taken for the light absorption of the calcium mirror to be halved is termed the lifetime. The method detects not only the reduction in the area of the calcium mirror from the margin and as a result of local reduction in the area, but also the homogeneous decrease in the layer thickness of the calcium mirror as a result of full-area reduction.

The measurement conditions selected were 85° C. and 85% relative humidity. The specimens were bonded in full-area form, without bubbles, with a PSA layer thickness of 50 μm. The breakdown of the Ca mirror is monitored by transmission measurements. The break-through time (lag time) is defined as the time required by moisture to travel the distance up to the Ca.

Unless otherwise indicated, all quantities in the examples which follow are weight percentages or parts by weight, based on the overall composition.

### EXAMPLE 1

The (co)polymer selected was a polystyrene-block-polyisobutylene block copolymer from Kaneka. Sibstar 103T (350 g) was used. The tackifier resin employed was Escorez 5300 (Ring and Ball 105°, DACP=71, MMAP=72) from ExxonMobil, a fully hydrogenated hydrocarbon resin (350 g). The reactive resin selected was Uvacure 1500 from Cytec, a cycloaliphatic diepoxide (300 g). These raw materials were dissolved in a mixture of cyclohexane (950 g) and acetone (50 g) to give a 50% by weight solution.

A latent-reactive thermally activatable initiator was then added to the solution. For this purpose, 3 kg of K-Pure TAG 2678 from King Industries were weighed off. The quantity of initiator was prepared as a 20% by weight solution in acetone and was added to the aforementioned mixture.

Using a knifecoating procedure, the formulation was coated from solution onto a siliconized PET liner and was dried at 70° C. for 60 minutes. The coatweight was 50 g/m². The specimen was lined with a further ply of a siliconized but less strongly releasing PET liner.

The activation temperature of these specimens according to Test J was 94° C. The activation temperature of these specimens according to Test K (in the 70° C. latency design) was likewise 94° C.; the standardized integral according to Test K was >99% relative to the integral from Test J.

These specimens were used to produce samples for bond strength measurements. After lamination of the specimen strips, the assembly was conditioned at 100° C. for 1 hour, and so the curing reaction was initiated. The bond strength on glass (float glass) was determined after equilibration at 23° C. and 50% relative humidity, and was 4.2 N/cm.

Further specimens were cured without lamination beforehand through the PET liner at 100° C. for 1 hour under conditions identical to those indicated above. These specimens were used for WVTR and OTR measurements (Mocon) and for the testing of optical properties.

The result from the WVTR measurement (Mocon) was 8 g/m²*d, and from the OTR measurement (Mocon) was 830 cm³/m²*d*bar.

Investigation of the optional properties of the cured specimens following removal of both PET liners produced a transmittance of 92% and a haze of 1.4%. The Δb* was 0.5.

### EXAMPLE 2

The (co)polymer selected was a polystyrene-block-polyisobutylene block copolymer from Kaneka. Sibstar 62M (375 g) was used. The tackifier resin employed was Regalite R1100 (Ring and Ball 105°, DACP=45, MMAP=75) from Eastman, a fully hydrogenated hydrocarbon resin (350 g). The reactive resin selected was Uvacure 1500 from Cytec, a cycloaliphatic diepoxide (275 g). These raw materials were dissolved in a mixture of cyclohexane (300 g) and heptane (700 g) to give a 50% by weight solution.

A latent-reactive thermally activatable initiator was then added to the solution. For this purpose, 3 kg of K-Pure TAG 2678 from King Industries were weighed off. The quantity of initiator was prepared as a 20% by weight solution in acetone and was added to the aforementioned mixture.

Using a knifecoating procedure, the formulation was coated from solution onto a siliconized PET liner and was dried at 70° C. for 60 minutes. The coatweight was 50 g/m². The specimen was lined with a further ply of a siliconized but less strongly releasing PET liner.

The activation temperature of these specimens according to Test J was 93° C. The activation temperature of these specimens according to Test K (in the 70° C. latency design) was 92° C.; the standardized integral according to Test K was >99% relative to the integral from Test J.

These specimens were used to produce samples for bond strength measurements. After lamination of the specimen strips, the assembly was conditioned at 100° C. for 1 hour, and so the curing reaction was initiated. The bond strength on glass (float glass) was determined after equilibration at 23° C. and 50% relative humidity, and was 5.9 N/cm.

Further specimens were cured without lamination beforehand through the PET liner at 100° C. for 1 hour under conditions identical to those indicated above. These specimens were used for WVTR and OTR measurements (Mocon) and for the testing of optical properties.

The result from the WVTR measurement (Mocon) was 8 g/m²*d, and from the OTR measurement (Mocon) was 780 cm³/m²*d*bar. For these specimens, moreover, a lifetime test was carried out. The lag time was 150 hours. This is surprising (and also surprisingly good in comparison to UV-initiated systems), since the more rapid curing reaction at the elevated temperature means that preliminary damage to the sensitive (opto)electronic material is likely (for example, as a result of chemical interaction or of internal mechanical stresses such as those caused, for example, by curing-associated contraction).

Investigation of the optical properties of the cured specimens following removal of both PET liners produced a transmittance of 91% and a haze of 1.7%. The Δb* was 0.5.

### EXAMPLE 3

The (co)polymer selected was a polystyrene-block-polyisobutylene block copolymer from Kaneka. Sibstar 73 T (300 g) was used. The tackifier resin employed was Regalite R1100 (Ring and Ball 105°, DACP=45, MMAP=75) from Eastman, a fully hydrogenated hydrocarbon resin, at 200 g. The reactive resin selected was Uvacure 1500 from Cytec, at 500 g. These raw materials were dissolved in a mixture of cyclohexane (950 g) and acetone (50 g) to give a 50% by weight solution.

A latent-reactive thermally activatable initiator was then added to the solution. For this purpose, 2.5 g of K-Pure CXC 1612 from King Industries were weighed off. The quantity of initiator was prepared as a 20% by weight solution in acetone and was added to the aforementioned mixture.

Using a knifecoating procedure, the formulation was coated from solution onto a siliconized PET liner and was dried at 60° C. for 60 minutes. The coatweight was 50 g/m². The specimen was lined with a further ply of a siliconized but less strongly releasing PET liner.

The activation temperature of these specimens according to Test J was 75° C. The activation temperature of these specimens according to Test K (in the 60° C. latency design) was 77° C.; the standardized integral according to Test K was 97% relative to the integral from Test J.

These specimens were used to produce samples for bond strength measurements. After lamination of the specimen strips, the assembly was conditioned at 100° C. for 1 hour, and so the curing reaction was initiated. The bond strength on glass (float glass) was determined after equilibration at 23° C. and 50% relative humidity, and was 3.9 N/cm.

Further specimens were cured without lamination beforehand through the PET liner at 80° C. for 1 hour under conditions identical to those indicated above. These specimens were used for WVTR and OTR measurements (Mocon) and for the testing of optical properties.

The result from the WVTR measurement (Mocon) was 10 g/m²*d, and from the OTR measurement (Mocon) was 860 cm³/m²*d*bar.

Investigation of the optical properties of the cured specimens following removal of both PET liners produced a transmittance of 91% and a haze of 1.5%. The Δb* was 0.6.

1. An adhesive, comprising
(a) at least one (co)polymer comprising at least isobutylene and/or butylene as a first comonomer kind and, optionally, at least one second comonomer kind which, when considered as hypothetical homopolymer, has a softening temperature of greater than 40° C.,
(b) at least one kind of an at least partly hydrogenated tackifier resin,
(c) at least one kind of a reactive resin based on a cyclic ether having a softening temperature of less than 40° C., and
(d) at least one kind of a latent-reactive thermally activatable initiator for initiating cationic curing.

2. The adhesive according to claim 1,
wherein
the (co)polymer or (co)polymers is or are homopolymers or random, alternating, block, star and/or graft copolymers having a molar mass M_{w} (weight average) of 1 000 000 g/mol or less, preferably 500 000 g/mol or less.

3. The adhesive according to claim 1,
wherein
polyisobutylene and/or polybutylene or mixtures of different polyisobutylenes and/or polybutylenes is used as the homopolymer.

4. The adhesive according to claim 1,
wherein
random copolymers of at least two different kinds of monomer, of which at least one is isobutylene or butylene, are used as the copolymers.

5. The adhesive according to claim 1,
wherein
the copolymer or copolymers is or are block, star and/or graft copolymers which contain at least one kind of a first polymer block (“soft block”) having a softening temperature of less than −20° C. and at least one kind of a second polymer block (“hard block”) having a softening temperature of greater than +40° C.

6. The adhesive according to claim 1,
wherein
resins which are compatible with the copolymer are used as the partly hydrogenated tackifier resins and/or,
where a polymer constructed from hard blocks and soft blocks is used, resins which are compatible primarily with the soft block are used as the partly hydrogenated tackifier resins.

7. The adhesive according to claim 1,
wherein
the partly hydrogenated tackifier resins have a tackifier resin softening temperature of 25° C.

8. The adhesive according to claim 1,
wherein
the adhesive comprises at least one adhesive resin which is an apolar resin having a diacetone alcohol cloud point (DACP) of above 30° C. and having a (mixed methylcyclohexane aniline point (MMAP) of greater than 50° C.

9. The adhesive according to claim 1,
wherein
fraction of tackifier resin(s) in the adhesive formula is at least 20 wt % and at most 60 wt %.

10. The adhesive according to claim 1,
wherein
the adhesive comprises at least one kind of a reactive resin based on a cyclic ether for the thermal crosslinking with a softening temperature in the uncured state of less than 40° C.

11. The adhesive according to claim 1,
wherein
the activation temperature of the latent-reactive thermal initiators is at most 125° C.

12. The adhesive according to claim 1,
wherein
the thermally activatable initiators are selected from the group consisting of pyridinium salts, ammonium salts, anilinium salts, sulphonium salts, thiolanium salts and lanthanoid triflates.

13. The adhesive according to claim 1,
wherein
the thermally activatable initiators are selected from the group of consisting of lanthanoid triflates.

14. The adhesive according to claim 1,
wherein
fraction of thermally activatable initiators in relation to amount of reactive resin used is at least 0.3 wt % and at most 2.5 wt %.

15. The adhesive according to claim 1,
wherein
the adhesive comprises one or more additives, selected from the group consisting of plasticizers, primary antioxidants, secondary antioxidants, process stabilizers, light stabilizers, processing assistants, endblock reinforcer resins, and polymers.

16. The adhesive according to claim 1,
wherein
the adhesive comprises one or more fillers nanoscale fillers, transparent fillers and/or getter and/or scavenger fillers.

17. The adhesive according to claim 1,
wherein
the adhesive is transparent in the visible light of the spectrum, which is wavelength ranging from about 400 nm to 800 nm.

18. The adhesive according to claim 1,
wherein
the adhesive exhibits a haze of less than 5.0%.

19. An adhesive tape comprising at least one layer of an adhesive according to claim 1 and a carrier, wherein the carrier has a permeation barrier of WVTR<0.1 g/(m² d) and OTR<0.1 cm³/(m² d bar).

20. The adhesive tape according to claim 16,
wherein
the carrier is a coated polymeric film.

21. The adhesive tape according to claim 16,
wherein
the carrier has a layer of a flexible thin glass with a layer thickness of not more than 1 mm.

22. The adhesive tape according to claim 18,
wherein
the thin glass is present in tape-like geometry.

23. A method of encapsulating an (opto)electronic arrangement comprising applying an adhesive, or a single-sided or double-sided adhesive tape formed with the adhesive according to claim 1 to a substrate.

24. The method according to claim 20,
wherein
the adhesive and/or regions of the electronic arrangement to be encapsulated are heated before, during and/or after the application of the adhesive.

25. The method according to claim 20,
wherein
the adhesive is cured partly or to completion on the electronic arrangement after application.

26. An electronic arrangement having an electronic structure, and a pressure-sensitive adhesive,
the electronic structure being at least partly encapsulated by the pressure-sensitive adhesive, wherein
the pressure-sensitive adhesive is an adhesive according to claim 1.
